(19) United States
(12) Patent Application Publication
(10) Pub. No.: US 2008/0180132 A1
(43) Pub. Date: Jul. 31, 2008

(54) Semiconductor device and method of fabricating the same

(75) Inventor: Hirotaka Ishikawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/010,265

(22) Filed: Jan. 23, 2008

(30) Foreign Application Priority Data
Jan. 25, 2007 (JP) 14486/2007

(51) Int. Cl. H03K 19/00

(52) U.S. Cl. 326/101

(57) ABSTRACT

This invention efficiently suppresses the power noise of an LSI. A semiconductor device includes first and second interconnection layers. The first interconnection layer has a source voltage supply line of a first potential positioned to extend along logic cells in a first direction. The second interconnection layer lies on an upper layer than the first interconnection layer and has plural source voltage supply lines of a second potential arranged adjacent to each other to form a group and positioned to extend in a second direction which is different from the first direction of interconnection. An interconnection line of the second potential is positioned on an upper layer than the first interconnection layer and interconnects at least two of the plurality of source voltage supply lines of the second potential. The interconnection line of the second potential is positioned to overlap the source voltage supply line of the first potential, to form a capacitor with the source voltage supply line of the first potential.

### BACKGROUND OF THE INVENTION

1. Field of the Invention

The present invention relates to semiconductor devices and more particularly to a semiconductor device having source interconnection of a multi-level mesh structure, and a method of fabricating the same.

2. Description of Related Art

In recent years, the integrated density of semiconductor LSIs (integrated circuits) has been raised increasingly. The multi-level mesh source interconnection technique for power supply has been frequently employed in LSIs in order to reduce the area occupied by the interconnection for power supply and make the interconnection designing flexible. Specifically, the multi-level mesh source interconnection technique is such that: plural source interconnection layers are formed vertically over logic elements; in each of the source interconnection layers a source voltage supply line (hereinafter will be referred to as “VDD line”) and a reference voltage supply line (e.g., ground voltage line, or GND line) are positioned in an alignment direction (i.e., direction of interconnection) that is different from an alignment direction in which the source voltage supply line and the reference voltage supply line of a different layer are positioned; and the GND line and VDD line of one layer are connected to the GND line and VDD line, respectively, of another layer by way of interlayer vias.

A variety of attempts have been made for reduction in noise of LSIs, which is an important challenge. For example, one such attempt is to stabilize power supply by arranging capacitive elements like the arrangement of logic elements in an LSI and connecting the capacitive elements to the power source, in order to reduce the power noise. This approach, however, has to provide an area required for the capacitive elements to be disposed and hence cannot allow a large number of capacitive elements to be disposed on an LSI having a relatively high integrated density.

JP-A No. 2006-173418 discloses the technique of reducing the power noise of LSIs of the type employing a two-level mesh source interconnection structure. According to this technique, an overlapped portion between the VDD line of a first layer of two source interconnection layers and the GND line of the second source interconnection layer forms a capacitor, while an overlapped portion between the GND line of the first source interconnection layer and the VDD line of the second source interconnection layer forms a capacitor. With this structure, each of the capacitors thus formed accumulates electric charge to stabilize the voltage across the opposite ends thereof, thereby making it possible to reduce the power noise due to power fluctuations. Further, since the overlapped portions between the supply lines of the two interconnection layers form capacitors, the noise can be reduced without using the area provided for disposition in the LSI.

### SUMMARY

The present invention seeks to solve one or more of the above problems, or to improve upon those problems at least in part.

In one embodiment, the semiconductor device includes a first interconnection layer having a source voltage supply line of a first potential positioned to extend along logic cells in a first direction, a second interconnection layer lying on an upper layer than the first interconnection layer and having plural source voltage supply lines of a second potential arranged adjacent to each other to form a group and positioned to extend in a second direction which is different from the first direction, and an interconnection line of the second potential positioned on an upper layer than the first interconnection layer and interconnecting at least two of the plurality of source voltage supply lines of the second potential. The interconnection line of the second potential is positioned to overlap the source voltage supply line of the first potential, to form a capacitor with the source voltage supply line of the first potential.

According to another aspect of the present invention, there is provided a method of fabricating a semiconductor device. This method includes the steps of: positioning in a first interconnection layer a source voltage supply line of a first potential so as to extend along logic cells in a first direction of interconnection; positioning in a second interconnection layer lying on a higher level than the first interconnection layer a group of source voltage supply lines of a second potential arranged adjacent to each other so as to extend in a second direction of interconnection which is different from the first direction of interconnection; positioning on a higher level than the first interconnection layer an interconnection line of the second potential interconnecting at least two of the plurality of source voltage supply lines of the second potential of the second interconnection layer so as to overlap the source voltage supply line of the first potential; and forming a capacitor by the interconnection line of the second potential and the source voltage supply line of the first potential.

According to the technique of the present invention, it is possible to efficiently suppress the power noise of an LSI, particularly, an LSI having the multi-level mesh source interconnection structure.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a view illustrating a common structure including logic cells and interconnection;

FIG. 2 is a plan view showing a semiconductor device according to a first embodiment of the present invention;

FIG. 3 is a three-dimensional view showing a portion cut out of the semiconductor device shown in FIG. 2;

FIG. 4 is a view illustrating a second embodiment of the present invention; and

FIG. 5 is a view illustrating a conventional technique.

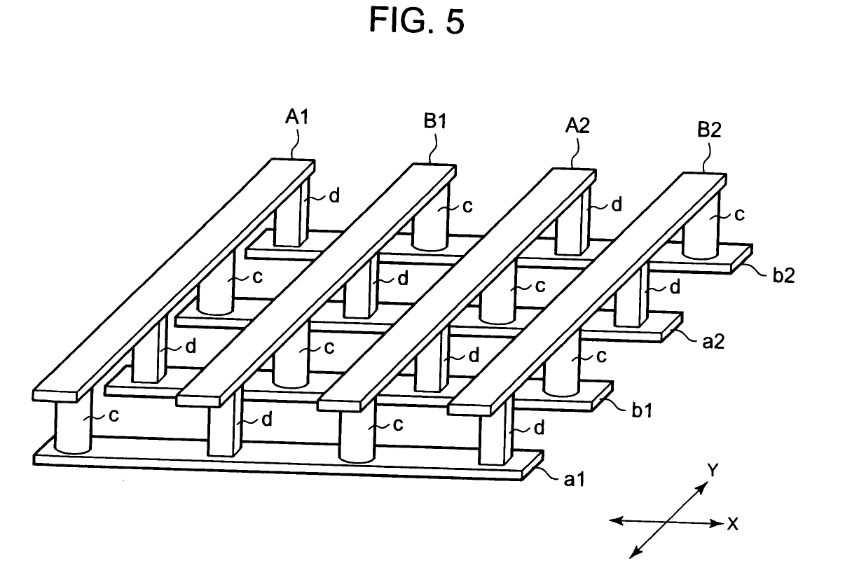

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purposes.

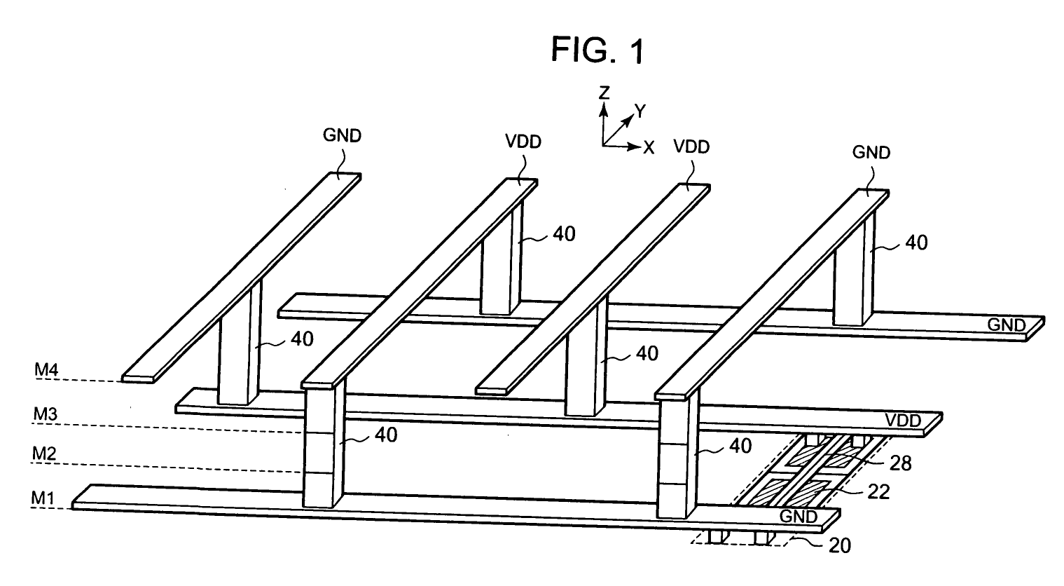

Before the detailed description of the embodiments of the present invention, a common structure including logic cells and interconnection in an LSI will be first described with reference to FIG. 1.

In FIG. 1, a portion encircled with dotted line is a logic cell 20. A logic cell is a combination of plural transistors disposed on a semiconductor substrate and comprises a basic logic circuit, such as AND or OR, and a buffer. By disposing plural such logic cells and providing these logic cells with interconnection, a semiconductor device can be obtained which is configured to perform a desired operation. Though FIG. 1 shows only one logic cell for simplification, plural logic cells are arranged actually. As shown in FIG. 1, the logic cell 20 is constructed of a diffused layer 22 hatched and transistors each having a gate 28. The source voltage and the ground voltage are supplied to each transistor from VDD lines and GND lines positioned in an interconnection layer (i.e., metal layer M1 in the example illustrated in FIG. 1) lying on a higher level than the layer in which the transistors are positioned, by way of contacts between the interconnection layers.

As shown in FIG. 1, a common structure in which the logic cells and the VDD lines and GND lines of interconnection layers are disposed is such that the VDD lines and GND lines are positioned to extend in X-direction and the logic cells are arranged along these interconnection lines. In a semiconductor device having multi-level interconnection, further VDD lines and GND lines are positioned in another interconnection layer lying on a higher level to supply the source voltage and the ground voltage connected thereto by way of vias provided between the interconnection layers. In the example illustrated in FIG. 1, there are provided four metal layers M1 to M4 above the layer having the transistors positioned therein and each of the metal layers M1 and M4 has VDD lines and GND lines which are connected to the VDD lines and the GND lines, respectively, of the other by way of interlayer vias 40.

Since the structure of each logic cell and the relation between the layer having the logic cells positioned therein and the interconnection layers in the following embodiments are each the same as in FIG. 1, description thereof will be omitted from the following description and a like reference character will be given to vias connecting the interconnection lines of one layer to those of another.

### First Embodiment

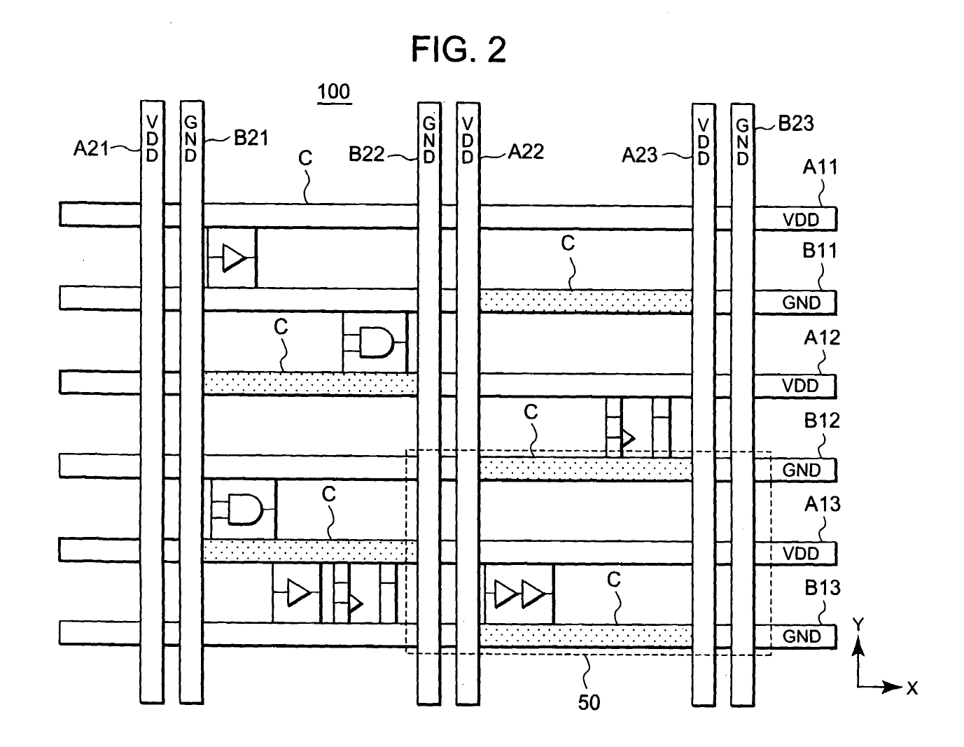

FIG. 2 is a plan view, as viewed from above, showing a semiconductor device 100 according to a first embodiment of the present invention. The semiconductor device 100, together with hard macro cells such as a memory device and a CPU core, forms an LSI chip. As shown, the semiconductor device 100 has logic elements, and VDD lines and GND lines for supplying a source voltage and a reference voltage (i.e., ground voltage in the example illustrated here), respectively, to these logic elements.

In the semiconductor device 100, interconnection for supplying power to the logic elements has a two-level mesh structure. VDD lines All, A12, and A13 and GND lines B11, B12, and B13 shown are arranged alternately in an interconnection layer lying above the logic elements (hereinafter will be referred to as “first interconnection layer”). These supply lines are positioned to extend in the same direction as the X-direction in which the logic elements are arranged.

Above the first interconnection layer, there is a second interconnection layer in which VDD lines A21, A22, and A23 and GND lines B21, B22, and B23 shown are positioned. These supply lines are positioned to extend in Y-direction perpendicular to the direction in which the supply lines of the first interconnection layer extend.

As shown in FIG. 2, the two types of supply lines, i.e., VDD lines and GND lines, of the second interconnection layer are disposed so that lines of the same source potential are arranged adjacent to each other to form groups and positioned to extend in the direction of interconnection. Further, the two types of supply lines shown in FIG. 2 are arranged so that adjacent groups have different source potentials, namely, GND, GND, VDD, VDD, GND, . . . .

Though pairs of interconnection lines form respective groups (VDD-VDD, GND-GND) in the example illustrated in FIG. 2, the number of interconnection lines forming one group is not limited to two. For example, it is possible that each of the groups consists of three interconnection lines like VDD-VDD-VDD or GND-GND-GND or the groups are different from each other in the number of interconnection lines, like VDD-VDD-VDD, GND-GND, VDD-VDD, and GND-GND-GND. The semiconductor device according to the present invention includes at least one group consisting of interconnection lines of the same source potential arranged adjacent to each other.

Now, attention is paid to the GND lines B21 and B22 forming a group in the second interconnection layer and the VDD line All of the first interconnection layer. A portion which extends between the GND lines B21 and B22 and overlaps the VDD line All forms a capacitor C.

Likewise, portions which extend between the GND lines B21 and B22 and overlap the VDD lines A12 and A13 of the first interconnection layer form respective capacitors C. Also, portions which extend between the VDD lines A22 and A23 and overlap the GND lines B11, B12 and B13 of the first interconnection layer form respective capacitors C.

That is, portions which extend between supply lines of the same type arranged adjacent to each other in the second interconnection layer and over lap the supply lines of a different type than the former type that are positioned in the first interconnection layer, form respective capacitors C.

Detailed description will be made of the structure of a capacitor C by cutting out a portion 50 encircled with dotted line in FIG. 2. This portion 50 will be referred to as “cutout portion” in the following description.

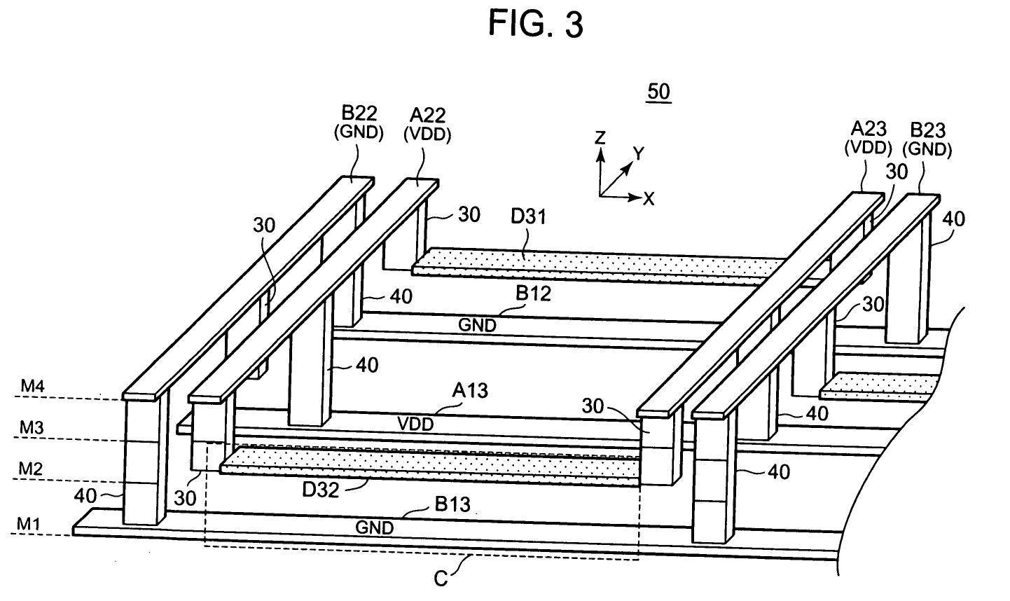

FIG. 3 is a three-dimensional view showing the cutout portion 50. As the cutout portion 50 is positioned higher than the layer in which the logic elements are arranged, the logic elements are not shown in FIG. 3 for easier understanding.

As shown in FIG. 3, the cutout portion 50 has four metal layers M1 to M4, the metal layer M1 corresponding to the first interconnection layer in which the GND line B12, VDD line A13, and GND line B13 are positioned, the metal layer M4 corresponding to the second interconnection layer in which the GND line B22, VDD line A22, VDD line A23, and GND line B23 are positioned.

Vias are provided between the supply lines of the metal layer M4 and those of the metal layer M1 at intersections of supply lines of the same type. Specifically, the GND lines B22 and B23 are connected to the GND lines B12 and B13 by way of vias 40, while the VDD lines A22 and A23 connected to the VDD line A13 by way of vias 40.

The VDD lines A22 and A23 positioned in the metal layer M4 are connected to the VDD lines D31 and D32 positioned in the metal layer M2 by way of vias 30. The VDD line D31 of the metal layer M2 extends between the VDD lines A22 and A23 and overlaps the GND line B12. Similarly, the VDD line D32 of the metal layer M2 extends between the VDD lines A22 and A23 and overlaps the GND line B13. The capacitors C, which are characteristic of the present invention, are respectively formed between the VDD line D31 connected to the VDD lines A22 and A23 and the GND line B12 and between the VDD line D32 connected to the VDD lines A22 and A23 and the GND line B13. In forming the capacitors C, an interlayer insulator (not shown) intervening the metal layers M1 and M2 serves as a dielectric.

Here, consideration will be given to the capacitance of a capacitor C. The capacitance of a capacitor C depends upon the area of an overlapped portion as mentioned above and, accordingly, the capacitance of the capacitor C that can be formed increases with increasing area of the overlapped portion. The area of the overlapped portion is determined by the spacing between two supply lines of the same type arranged adjacent to each other in the second interconnection layer. For this reason, the spacing between adjacent ones of the supply lines positioned in the second interconnection layer is such that the spacing between adjacent supply lines of the same type is larger than that between adjacent supply lines of different types. With a view to providing each capacitor C with the largest possible capacitance, the spacing between adjacent supply lines of different types is preferably a minimum value that can be attained under limitations on the design or interconnection.

While the VDD lines D31 and D32 are positioned to extend between the VDD lines A22 and A23 in FIG. 3, the VDD lines D31 and D32 can be further extended in the X-direction, i.e., toward the GND line B22 beyond the VDD line A22 and toward the GND line B23 beyond the VDD line A23. The capacitance of each capacitor C can be increased by thus further extending the VDD lines D31 and D32.

As described above, the semiconductor device 100 according to the present embodiment includes: a power supply line (VDD or GND) of the metal layer M1 that is formed to extend along the logic cells; supply lines of the same source potential that are arranged adjacent to each other to form a group in the metal layer M4 and are different in potential from the power supply line of the metal layer M1; and a power supply line (GND or VDD) that is positioned to extend between the supply lines of the metal layer M4 and overlap the power supply line of the metal layer M1. A capacitor C is formed between the power supply line of the metal layer M1 and the power supply line overlapping it. By contrast to a semiconductor device provided with capacitor cells, the semiconductor device 100 thus constructed according to the present embodiment allows capacitors each having an increased capacitance to be positioned in the vicinity of the logic cells without any effect on the area provided for disposition in the semiconductor device.

Switching noise caused by peak currents that occur during the switching operations of logic elements makes up a large proportion of the power noise of an LSI. Such switching noise can be suppressed more efficiently as a capacitor is positioned closer to the logic elements. In the semiconductor device 100, the supply lines of the first interconnection layer are positioned to extend in the X-direction which is the same as the direction in which the logic elements are arranged, while the supply lines of the second interconnection layer positioned to extend in the Y-direction perpendicular to the direction in which the logic elements are arranged. Accordingly, capacitors Care formed to extend along the logic elements arranged, thereby making it possible to suppress the switching noise efficiently.

### Second Embodiment

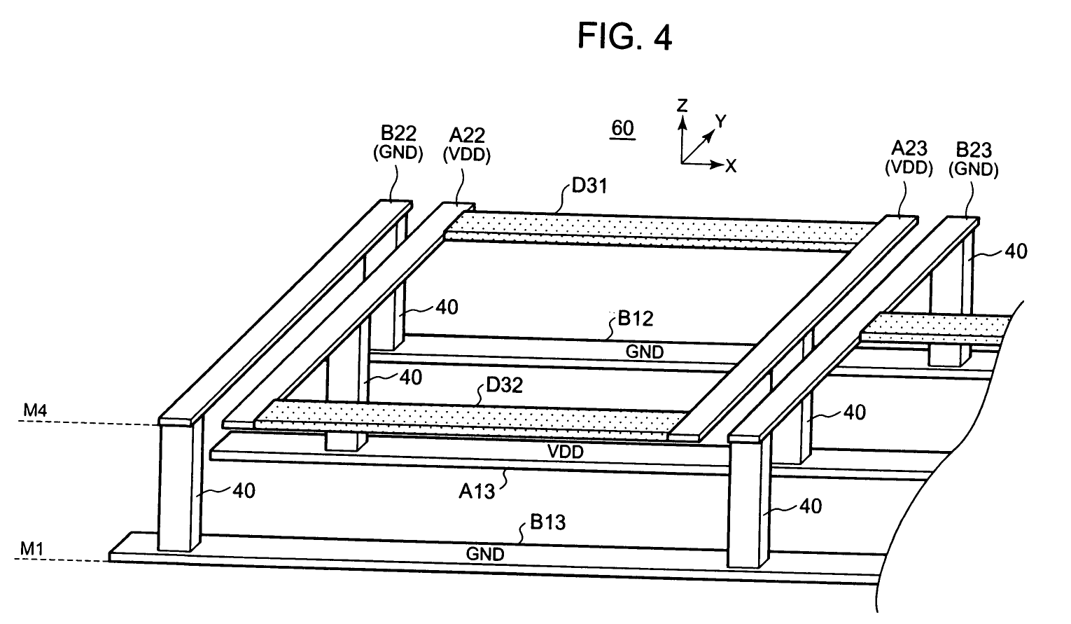

FIG. 4 shows a cutout portion 60, corresponding to the cutout portion 50 shown in FIG. 3, of a semiconductor device according to a second embodiment of the present invention. Like reference characters are used designate like or corresponding parts throughout FIGS. 3 and 4 in order to omit detailed description thereof.

While the foregoing semiconductor device 100 according to the first embodiment has the four metal layers M1 to M4, a semiconductor device according to the present invention can be realized without the provision of the metal layers M2 and M3, i.e., with the provision of only two metal layers M1 and M4. Though the second embodiment shown in FIG. 4 has two metal layers, the reference characters M1 and M4 each remain the same to designate the two metal layers for simplification of description.

In the case of the provision of only two metal layers as shown in FIG. 4, VDD lines D31 and D32 are positioned in the second metal layer M4 and connected directly to VDD lines A22 and A23 of the metal layer M4. Capacitors C (not shown) are formed between the VDD lines D32 and D31 of the second metal layer M4 and the GND lines B12 and B13 of the first metal layer M1.

The semiconductor device thus constructed can enjoy the same advantage as the semiconductor device 100 shown in FIG. 2.

In a common LSI chip fabricating process, logic elements are wired after the formation of power supply lines. In the case of the example illustrated in FIG. 4, the logic elements are wired after the positioning of the supply lines of the metal layers M1 and M4 and the interconnection between these supply lines by way of vias have been completed. In the structure shown in FIG. 4, the VDD lines D31 and D32 for forming capacitors extend over the inside spacing between the two opposite lines A22 and A23 to connect to these lines A22 and A23. Therefore, the VDD lines D31 and D32 can be formed even after the logic elements have been wired. This makes it possible to form a capacitor C only in a region that can accommodate an additional capacitor therein after the logic elements have been wired, thereby imparting an LSI chip with enhanced flexibility of interconnection.

The present invention has been described based on the foregoing embodiments. These embodiments are illustrative and may be variously modified or varied without departing from the spirit of the present invention. Those skilled in the art will understand that varied embodiments containing such modifications or variations are within the scope of the present invention.

For example, the VDD lines D31 and D32 for forming capacitors are positioned in the metal layer M2 according to the embodiment shown in FIG. 2. However, the positioning of such lines for forming capacitors is not limited to the positions specifically noted herein as long as capacitors according to the technique of the present invention can be formed between two interconnection layers each having source voltage supply lines and reference voltage supply lines positioned therein.

In the embodiment shown in FIG. 2, the two metal layers M2 and M3 are provided between the two interconnection layers (i.e., metal layers M1 and M4) each having source voltage supply lines and reference voltage supply lines positioned therein. However, the number of such metal layers provided between the two interconnection layers each having source voltage supply lines and reference voltage supply lines positioned therein is not limited to the numbers specifically noted herein as long as capacitors according to the technique of the present invention can be formed.

The vertical positional relationship between the first and second interconnection layers in each of the foregoing embodiments may be reversed.

It is apparent that the present invention is not limited to the above embodiments, but may be modified and changed without departing from the scope and sprit of the invention.

What is claimed is:

1. A semiconductor device, comprising:
a first interconnection layer which includes a source voltage supply line of a first potential positioned to extend along logic cells in a first direction;
a second interconnection layer disposed on an upper layer than said first interconnection layer and including a plurality of source voltage supply lines of a second potential arranged adjacent to each other to form a group and positioned to extend in a second direction which is different from said first direction; and
an interconnection line of the second potential disposed on an upper layer than said first interconnection layer and interconnecting at least two of said plurality of source voltage supply lines of the second potential,
said interconnection line of the second potential being positioned to overlap said source voltage supply line of the first potential, to form a capacitor with said source voltage supply line of the first potential.

2. The semiconductor device according to claim 1, wherein said interconnection line of the second potential is positioned in an interconnection layer intervening between said first interconnection layer and said second interconnection layer and is connected to said source voltage supply lines of the second potential by way of vias.

3. The semiconductor device according to claim 1, wherein said interconnection line of the second potential is positioned in said second interconnection layer.

4. The semiconductor device according to claim 1, wherein:
said logic cells are arranged in plural rows; and
said first interconnection layer has a plurality of source voltage supply lines of the first potential and a plurality of source voltage supply lines of the second potential which are arranged alternately to extend along said logic elements in said first direction of interconnection.

5. The semiconductor device according to claim 1, wherein said group is a first group, said interconnection line is a first interconnection line and wherein:
said first interconnection layer further has a source voltage supply line of the second potential positioned to extend along said logic cells in said first direction;
said second interconnection layer further has a plurality of source voltage supply lines of the first potential which are arranged adjacent to each other to form a second group and positioned to extend in said second direction;
a second interconnection line of the first potential is further provided on an upper layer than said first interconnection layer to interconnect at least two of said plurality of source voltage supply lines of the first potential of said second interconnection layer; and
said second interconnection line of the first potential is positioned to overlap said source voltage supply line of the second potential of said first interconnection layer, to form a capacitor with said source voltage supply line of the second potential.

6. The semiconductor device according to claim 5, wherein said first group of said source voltage supply lines of the first potential and said second group of said source voltage supply lines of the second potential are arranged adjacent to each other in said second interconnection layer in such a manner that adjacent ones of said source voltage supply lines of each of said groups define a spacing therebetween which is larger than a spacing between adjacent ones of intergroup source voltage supply lines.
